(19) United States
(12) Patent Application Publication
(10) Pub. No.: US 2013/0285096 A1
(43) Pub. Date: Oct. 31, 2013

(54) LIGHT EMITTING DIODE PACKAGE AND METHOD FOR MANUFACTURING THE SAME

(71) Applicant: ADVANCED OPTOELECTRONIC TECHNOLOGY, INC., Hsinchu Hsien (TW)

(72) Inventors: YU-FANG TSENG, Hsinchu (TW); CHIA-WEN HSIAO, Hsinchu (TW)

(73) Assignee: ADVANCED OPTOELECTRONIC TECHNOLOGY, INC., Hsinchu Hsien (TW)

(21) Appl. No.: 13/865,211

(22) Filed: Apr. 18, 2013

(30) Foreign Application Priority Data
Apr. 25, 2012 (CN) 201210123517.0

(51) Int. Cl. H01L 33/54

(52) U.S. Cl. CPC H01L 33/54
USPC 257/98; 438/27

(57) ABSTRACT

A method for manufacturing a light emitting diode (LED) package comprises: providing a substrate having a first electrode and a second electrode electrically insulated from the first electrode, wherein an LED die is mounted on the first electrode and electrically connected to the first electrode and the second electrode; forming a first encapsulant layer on the substrate to encapsulate the LED die therein, the first encapsulant layer being colloidal; forming a nitride compound phosphor layer distributed on an outer face of the first encapsulant layer; and heating the first encapsulant layer to solidify the first encapsulant layer. A second encapsulant layer is formed on the nitride compound phosphor layer to encapsulate the first encapsulant layer. An LED package formed by the method is also provided.

### TECHNICAL FIELD

The present disclosure relates generally to semiconductor devices, and more particularly to a light emitting diode (LED) package and a method for manufacturing the same, wherein the LED package has an improved color rendering index by an evenly distributed nitride compound phosphor layer.

### DESCRIPTION OF RELATED ART

LEDs are solid state light emitting devices formed of semiconductors, which are more stable and reliable than other conventional light sources such as incandescent bulbs. Thus, LEDs are being widely used in various fields such as numeral/character displaying elements, signal lights, light sources for lighting and display devices. In use, providing LEDs in packages can provide protection, color selection, focusing and the like for light emitted by the LEDs. Generally, a process of packaging an LED die includes bonding, encapsulating, baking, cutting etc..

In a typical encapsulating process, the dispensing machine dispenses amount of phosphor glue containing a YAG phosphor scattered therein to encapsulate a blue LED die mounted on a substrate to generate a white light, whereas such an LED package always has a low color rendering index due to lack of red light.

In order to improve the color rendering performance of the LED package, it's likely to dispense the phosphor glue containing YAG and red phosphor scattered therein directly over a blue LED die. However, the red phosphor is a nitride compound and likely to cake or deposit in the phosphor glue, and this will result in an uneven distribution of the red phosphor surrounding the LED die, thereby producing a non-uniform color distribution. Therefore, such an LED package is difficult to satisfy the requirements of uniform phosphor distribution and high color rendering index.

What is needed therefore is an LED package and method for manufacturing the same which can overcome the above mentioned limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is a cross sectional view of an LED (light emitting diode) package in accordance with an exemplary embodiment of the present disclosure.

FIG. 2 is a flow chart of a method for manufacturing the LED (light emitting diode) package in accordance with an exemplary embodiment of the present disclosure.

FIGS. 3-5 are cross sectional views showing different steps of the method of FIG. 2 in obtaining the LED (light emitting diode) package of FIG. 1.

### DETAILED DESCRIPTION

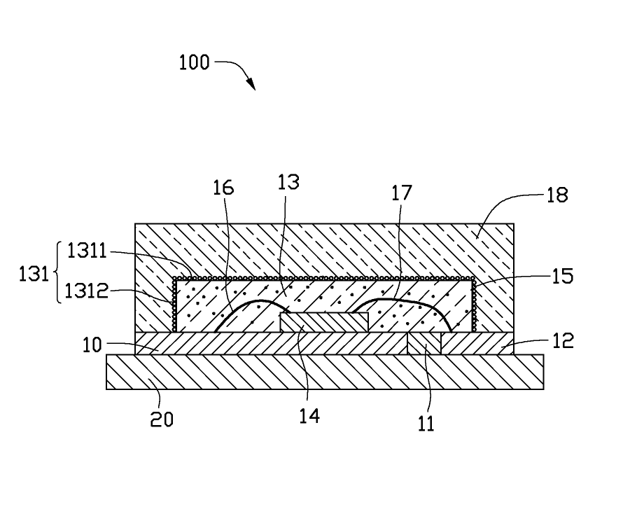

Referring to FIG. 1, a light emitting diode (LED) package 100 in accordance with an exemplary embodiment of the present disclosure includes a substrate 20 having a first electrode 10 and a second electrode 12 electrically insulated from the first electrode 10, an LED die 14 mounted on the first electrode 10, a first encapsulant layer 13 formed on the substrate 20 to encapsulate the LED die 14, and a second encapsulant layer 18 covering the first encapsulant layer 13.

The first and second electrodes 10, 12 are spaced from each other to form a gap (not labeled) therebetween. An insulating layer 11 is formed in the gap to electrically insulate the first electrode 10 from the second electrode 12. The first and second electrodes 10, 12 and the insulating layer 11 have an identical thickness, and are in the same level. The LED die 14 is electrically connected to the first electrode 10 and the second electrode 12 via wires 16, 17, respectively. In another preferred embodiment, the LED die 14 could be electrically mounted on the first electrode 10 and the second electrode 12 in a manner of flip-chip, whereby the wires 16, 17 can be omitted.

The first encapsulant layer 13 contains YAG (yttrium aluminum garnet) phosphor (not labeled) scattered therein. The first encapsulant layer 13 has an outer face 131, wherein the outer face 131 includes a top face 1311 distant from the first electrode 10 and an annular lateral wall 1312 extending downwardly from a periphery of the top face 1311 to reach the first and second electrodes 10, 12.

The second encapsulant layer 18 is formed on the first and second electrodes 10, 12 on the substrate 20 to fully cover the first encapsulant layer 13. The second encapsulant layer 18 has a recessed inner face (not labeled) surrounding the first encapsulant layer 13. A nitride compound phosphor layer 15 is formed between the outer face 131 of the first encapsulant layer 13 and the recessed inner face of the second encapsulant layer 18, wherein the nitride compound phosphor layer 15 is adhered to the outer face 131 of the first encapsulant layer 13. The nitride compound phosphor layer 15 is made of red nitride compound phosphor powder and evenly distributed on the top face 1311 and the annular lateral wall 1312 of the outer face 131 of the first encapsulant layer 13.

In the present disclosure, the LED die 14 is a high-brightness GaN blue LED die and the first encapsulant layer 13 contains YAG phosphor scattered therein. The YAG phosphor absorbs blue light emitted from the LED die 14 and re-emits yellow light, with a portion of the blue light from the LED die 14 leaking through the first encapsulant layer 13. The nitride compound phosphor layer 15 emits red light by an excitation of the portion of blue light leaking through the first encapsulant layer 13. Thus, a warm white light having a high rendering color index is obtained by mixing the blue light, the yellow light and the red light.

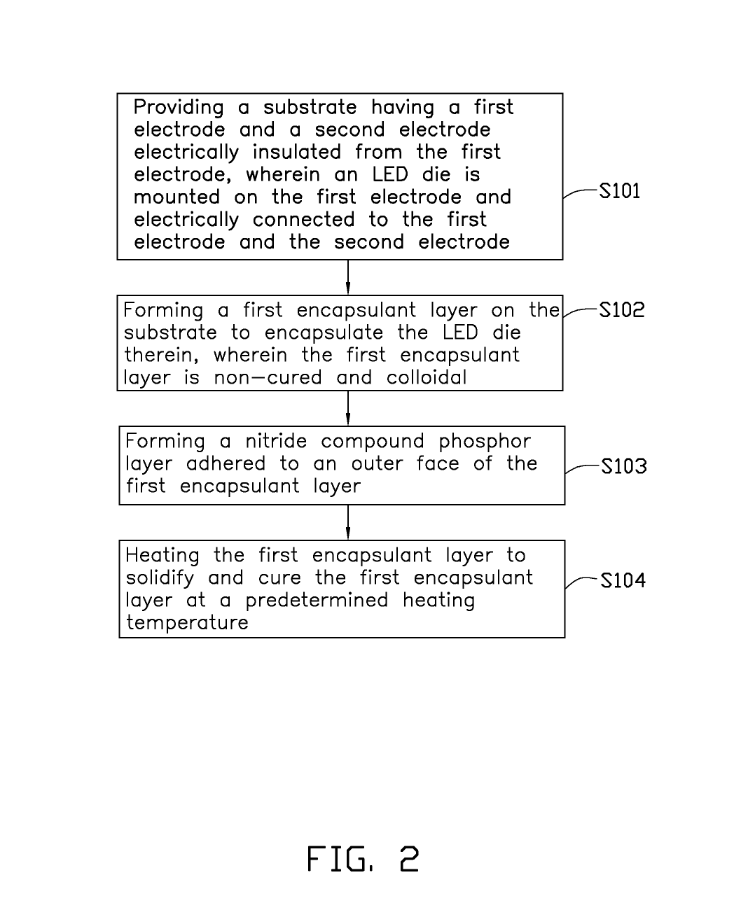

FIG. 2 illustrates a flow chart of a method for manufacturing the light emitting diode (LED) package 100. The method includes the following steps:

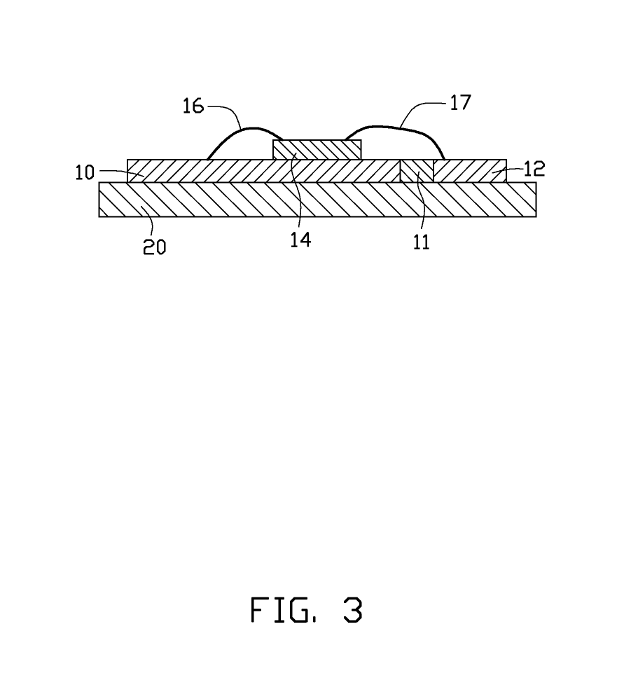

In step A (also referring to FIG. 3), a substrate 20 having a first electrode 10 and a second electrode 12 electrically insulated from the first electrode 10 is provided.

The first and second electrodes 10, 12 are spaced from each other to form a gap (not labeled) therebetween. An insulating layer 11 is formed in the gap to electrically insulate the first electrode 10 from the second electrode 12. The first and second electrodes 10, 12 and the insulating layer 11 have an identical thickness, and are in the same level. An LED die 14 is mounted on the first electrode 10 and electrically connected to the first and second electrodes 10, 12 via wires 16, 17, respectively.

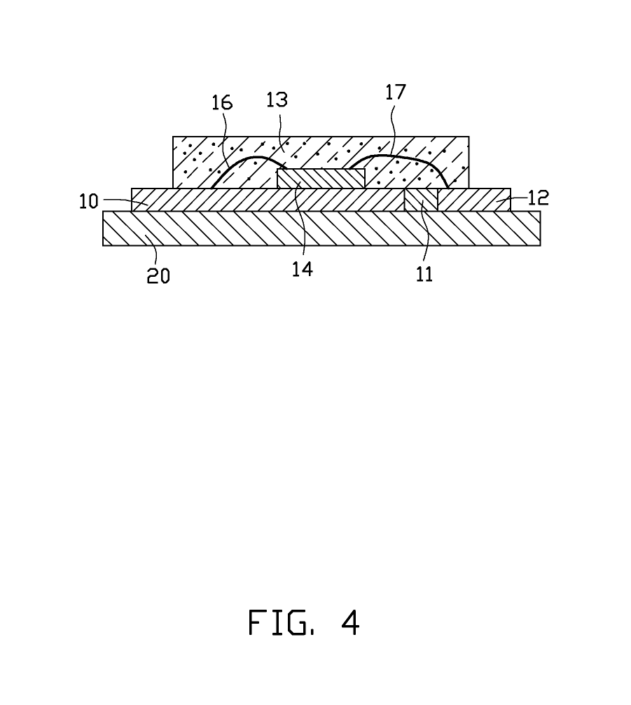

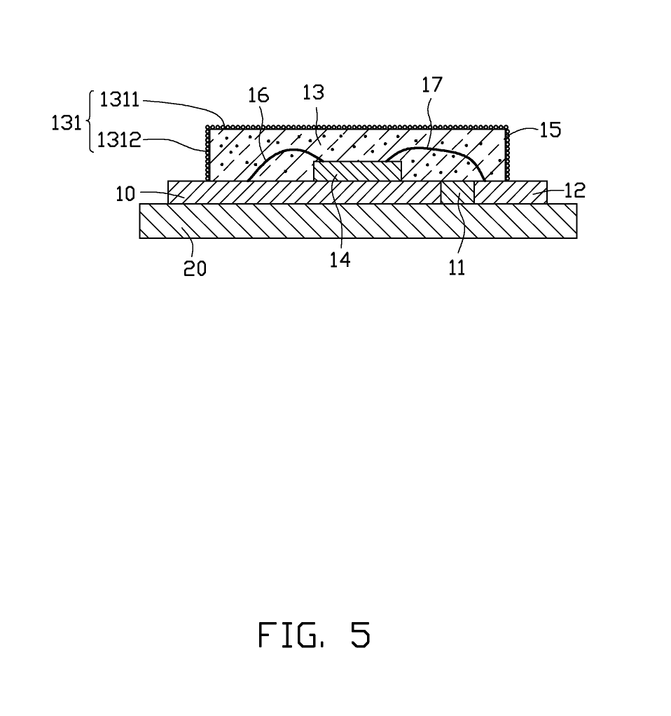

In step B (also referring to FIG. 4), a first encapsulant layer 13 which is not cured is formed on top faces (not labeled) of the first and second electrodes 10, 12 and the insulating layer 11 on the substrate 20 to encapsulate the LED die 14. The first encapsulant layer 13 contains YAG phosphor (not labeled) scattered therein. In the present disclosure, the LED die 14 is a high brightness GaN LED die. The first encapsulant layer 13 has an outer face 131, wherein the outer face 131 includes a top face 1311 distant from the first electrode 10 and an annular lateral wall 1312 extending downwardly from a periphery of the top face 1311 to reach the first and second electrodes 10, 12. Thereafter, an adhesive (not shown) is applied on the outer face 131 to increase adhesion of the first encapsulant layer 13. In this state, the first encapsulant layer 13 has a colloidal (jelly-like) composition.

In step C, a nitride compound phosphor layer 15 is adhered to the outer face 131 of the encapsulant layer 13. The nitride compound phosphor layer 15 is made of red nitride compound phosphor powder and evenly distributed on the outer face 131 of the first encapsulant layer 13 by spraying the red nitride compound phosphor powder onto the outer surface 131. The nitride compound phosphor layer 15 is adhered to the outer surface 131 due to the adhesion of the first encapsulant layer 13 and the adhesive applied on the outer surface 131 of the encapsulant layer 13.

In step D, the first encapsulant layer 13 is heated at a predetermined heating temperature until the first encapsulant layer 13 is cured and solidified. In the present disclosure, the predetermined heating temperature is ranged from about 150 degrees Celsius to about 180 degrees Celsius.

Thereafter (also referring to FIG. 1), a second encapsulant layer 18 is formed on the first and second electrodes 10, 12 on the substrate 20 to fully cover the first encapsulant layer 13. The second encapsulant layer 18 has a recessed inner face surrounding the first encapsulant layer 13. The phosphor layer 15 is distributed on the outer face 131 of the first encapsulant layer 13 and located between the outer face 131 of the first encapsulant layer 13 and the recessed inner face of the second encapsulant layer 18. The first and second encapsulant layers 13, 18 are made of transparent material, such as silicone or epoxy. Alternatively, the second encapsulant layer 18 could contain a green phosphor scattered therein.

It is understood that the step of heating the first encapsulant layer 13 to solidify the first encapsulant layer 13 could be implemented after forming the second encapsulant layer 18 to cover the first encapsulant layer 13.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A light emitting diode (LED) package comprising:
a substrate;
a first electrode and a second electrode formed on the substrate, wherein the first electrode and the second electrode are electrically insulated from each other;
an LED die mounted on the first electrode and being electrically connected to the first and second electrodes;
a first encapsulant layer formed on the substrate to encapsulate the LED die therein;
an nitride compound phosphor layer distributed on an outer face of the first encapsulant layer;
wherein the nitride compound phosphor layer is made of red nitride compound phosphor powder.

2. The LED package of claim 1, wherein the outer face of the first encapsulant layer comprises a top face distant from the first electrode and a lateral wall extending downwardly from a periphery of the top face toward the substrate.

3. The LED package of claim 1, further comprising a second encapsulant layer formed on the substrate to cover the first encapsulant layer, wherein the nitride compound phosphor layer is located between the first encapsulant layer and the second encapsulant layer.

4. A method for manufacturing a light emitting diode (LED) package comprising:
providing a substrate having a first electrode and a second electrode electrically insulated from the first electrode, wherein an LED die is mounted on the first electrode and electrically connected to the first electrode and the second electrode;
forming a first encapsulant layer on the substrate to encapsulate the LED die therein, wherein the first encapsulant layer is non-cured and colloidal;
forming a nitride compound phosphor layer adhered to an outer face of the first encapsulant layer; and
heating the first encapsulant layer to solidify and cure the first encapsulant layer at a predetermined heating temperature.

5. The method of claim 4, further comprising a step of forming a second encapsulant layer on the substrate to cover the first encapsulant layer after heating the first encapsulant layer, wherein the nitride compound phosphor layer is located between the first encapsulant layer and the second encapsulant layer.

6. The method of claim 4, further comprising a step of forming an adhesive on the outer face of the first encapsulant layer after forming the first encapsulant layer and before forming the nitride compound phosphor layer.

7. The method of claim 4, wherein the nitride compound phosphor layer is made of red nitride compound phosphor powder sprayed on the outer face of the first encapsulant layer.

8. The method of claim 4, wherein the outer face of the first encapsulant layer comprises a top face distant from the first and second electrodes and a lateral wall extending downwardly from a periphery of the top face toward the first and second electrodes.

9. The method of claim 5, wherein the second encapsulant layer has a recessed inner face surrounding the first encapsulant layer.

10. The method of claim 9, wherein the nitride compound phosphor layer is located between the outer face of the first encapsulant layer and the recessed inner face of the second encapsulant layer.

11. The method of claim 4, wherein the predetermined heating temperature is ranged from 150 degrees Celsius to 180 degrees Celsius.

12. The method of claim 4, wherein the first encapsulant layer contains YAG phosphor scattered therein.

13. A method for manufacturing a light emitting diode (LED) package comprising:
providing a substrate having a first electrode and a second electrode electrically insulated from the first electrode, wherein an LED die is mounted on the first electrode and electrically connected to the first electrode and the second electrode; forming a first encapsulant layer on the substrate to encapsulate the LED die therein, wherein the first encapsulant layer is non-cured and has a colloidal composition;
forming a nitride compound phosphor layer distributed on an outer face of the first encapsulant layer;
forming a second encapsulant layer on the substrate to cover the first encapsulant layer, wherein the nitride compound phosphor layer is located between the first encapsulant layer and the second encapsulant layer; and
heating the first encapsulant layer to solidify the first encapsulant layer at a predetermined heating temperature.

14. The method of claim 13, further comprising a step of forming an adhesive on the outer face of the first encapsulant layer after forming the first encapsulant layer and before forming the nitride compound phosphor layer.

15. The method of claim 13, wherein the nitride compound phosphor layer is made of red nitride compound phosphor powder sprayed on the outer face of the first encapsulant layer.

16. The method of claim 13, wherein the outer face of the first encapsulant layer comprises a top face distant from the first and second electrodes and a lateral wall extending downwardly from a periphery of the top face toward the first and second electrodes.

17. The method of claim 13, wherein the second encapsulant layer has a recessed inner face surrounding the first encapsulant layer.

18. The method of claim 17, wherein the nitride compound phosphor layer is located between the outer face of the first encapsulant layer and the recessed inner face of the second encapsulant layer.

19. The method of claim 13, wherein the predetermined heating temperature is ranged from 150 degrees Celsius to 180 degrees Celsius.

20. The method of claim 13, wherein the first encapsulant layer contains YAG phosphor scattered therein.
